(19) United States
(12) Patent Application Publication
(10) Pub. No.: US 2009/0130818 A1
(43) Pub. Date: May 21, 2009

(54) METHOD FOR FORMING SHALLOW TRENCH ISOLATION STRUCTURE AND METHOD FOR PREPARING RECESSED GATE STRUCTURE USING THE SAME

(75) Inventor: TSUNG TE LIN, TAICHUNG CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 12/022,044

(22) Filed: Jan. 29, 2008

(30) Foreign Application Priority Data
Nov. 21, 2007 (TW) 096144014

(51) Int. Cl. H01L 21/283; H01L 21/762

(52) U.S. Cl. 438/424; 438/589; 257/E21.159; 257/E21.545

(57) ABSTRACT

A method for preparing a recessed gate structure comprises the steps of: forming a shallow trench isolation structure surrounding an active area in a silicon substrate, wherein an etching barrier layer is formed on the surface of the shallow trench isolation structure; forming a plurality of gate trenches in the active area of the silicon substrate by performing an etching process; and forming a recessed gate structure by filling the gate trench with a predetermined height.

### BACKGROUND OF THE INVENTION

(A) Field of the Invention

The present invention relates to a method for forming a shallow trench isolation structure and a method for preparing a recessed gate structure using the same, and more particularly, to a method for forming a shallow trench isolation structure without forming parasitic transistors and a method for preparing a recessed gate structure using the same.

(B) Description of the Related Art

Conventional integrated circuit fabrication processes use a local oxidation of silicon (LOCOS) technique or shallow trench isolation (STI) technique to electrically isolate wafer-mounted electronic devices from each other, so as to avoid short circuits and cross interference. Due to the LOCOS technique's forming a field oxide layer covering a larger wafer area and also because it forms a “bird's beak” pattern, advanced integrated circuit fabrication generally selects the STI technique to electrically isolate electronic devices.

FIG. 1 to FIG. 7 illustrate a method for preparing a recessed gate structure according to the prior art. FIG. 1 is a top view of a shallow trench isolation structure and an active area on a semiconductor substrate, FIG. 2 to FIG. 5 are cross-sectional views along a cross-sectional line I-I in FIG. 1, and FIG. 7 is a cross-sectional view along a cross-sectional line II-II in FIG. 6 according to the prior art. The following paragraphs describe the preparation of the recessed gate structure according to the prior art.

Referring to FIG. 1 and FIG. 2, a plurality of shallow trench isolation structures 14 are formed in a semiconductor substrate 12, and the shallow trench isolation structures 14 surround an active area 16. Referring to FIG. 3, a pad oxide layer 18 covering the semiconductor substrate 12 is formed, and an etching mask 20 having a plurality of openings 22 is then formed on the pad oxide layer 18.

Referring to FIG. 4, a dry etching process is performed to remove a portion of the semiconductor substrate 12 under the openings 22 of the etching mask 20 so as to form a plurality of gate trenches 24 in the semiconductor substrate 12. The etching gas of the dry etching process has a small etching selectivity between the silicon of the semiconductor substrate 12 and the silicon oxide of the pad oxide layer 18 as well as the shallow trench isolation structure 14. Consequently, the dry etching process not only removes the portion of the semiconductor substrate 12 under the opening 22 to form the gate trenches 24, but also removes the pad oxide layer 18 as well as the shallow trench isolation structure 14 to form a plurality of depressions 26 in the shallow trench isolation structure 14.

Referring to FIG. 5, after removing the etching mask 20, recessed gates 28 filling the gate trenches 24 and word lines 30 connecting the recessed gates 28 are formed, and FIG. 6 is the top view of the semiconductor substrate 12 after the recessed gates 28 and the word line 30 are formed. The subsequently formed word lines 30 also fill the depressions 20 to form parasitic transistors 34 at the interface between the active area 16 and the shallow trench isolation structure 14.

Referring to FIG. 7, the parasitic transistors 34 consist of the word lines (serving as a gate) 30 above the semiconductor substrate 12, the recessed gate 28 (serving as a source) in the semiconductor substrate 12, and the doped region serving as drain.

Due to the influence of the parasitic transistor 34, increasing the depth of the gate trenches 24 decreases the threshold voltage of the transistor having the recessed gate structure. Thus, the small etching selectivity of the etching gas between the semiconductor substrate and the silicon oxide (the pad oxide layer as well as the shallow trench isolation structure) results in forming a plurality of depressions in the shallow trench isolation structure by the dry etching process, which leads to the problem of forming the parasitic transistor at the corner of the active area.

### SUMMARY OF THE INVENTION

One aspect of the present invention provides a method for forming a shallow trench isolation structure and a method for preparing a recessed gate structure using the same, which does not form a depression in an upper portion of the shallow trench isolation structure and so avoids the formation of parasitic transistors at the corner of the active area.

A method for forming a shallow trench isolation structure according to this aspect of the present invention comprises the steps of forming a trench isolation region in a semiconductor substrate, forming a dielectric stack on the sidewall of the trench isolation region, forming an isolation dielectric layer filling the trench isolation region, and forming an etching barrier layer on the surface of the isolation dielectric layer close to an open end of the trench isolation region such that the etching gas of the subsequent etching process has a high etching selectivity between the etching barrier layer and the semiconductor substrate.

Another aspect of the present invention provides a method for preparing a recessed gate structure comprising a step of forming a trench isolation region in a semiconductor substrate, wherein the trench isolation region surrounds an active area and an etching barrier layer is formed on the surface of the trench isolation region. An etching process is then performed to define a plurality of gate trenches, which are filled to form a recessed gate structure with a predetermined height.

The present invention forms the etching barrier layer on the surface of the isolation dielectric layer close to the open end of the trench isolation region such that the etching gas can have a high etching selectivity between the etching barrier layer and the semiconductor substrate. Consequently, the subsequent dry etching process for forming the gate trenches will not form a depression in the shallow trench isolation structure, and so avoids the formation of the parasitic transistor at the corner of the active area.

### BRIEF DESCRIPTION OF THE DRAWINGS

The objectives and advantages of the present invention will become apparent upon reading the following description and upon reference to the accompanying drawings in which:

FIG. 1 is a top view of a shallow trench isolation structure and an active area on a semiconductor substrate according to the prior art;

FIG. 2 to FIG. 5 are cross-sectional views along a cross-sectional line I-I in FIG. 1, showing the fabrication process of the recessed gate structure according to the prior art;

FIG. 7 is a cross-sectional view along a cross-sectional line II-II in FIG. 6 according to the prior art; and

FIG. 8 to FIG. 15 illustrate a method for preparing a recessed gate structure according to one embodiment of the present invention.

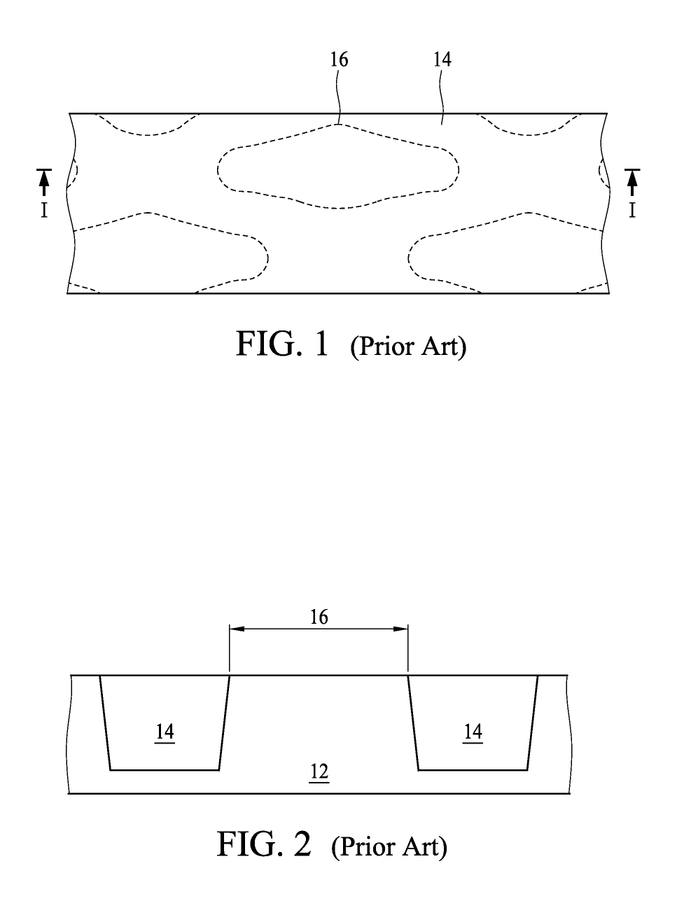

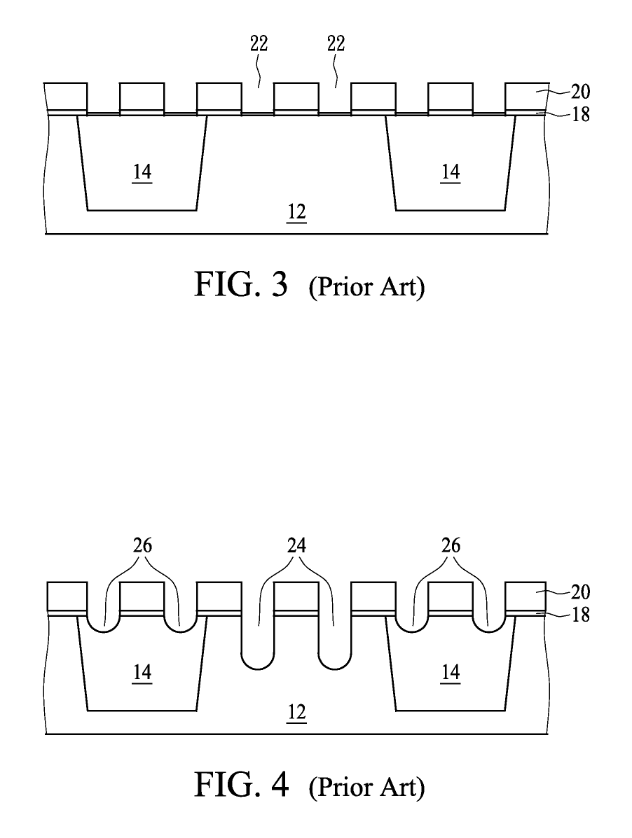

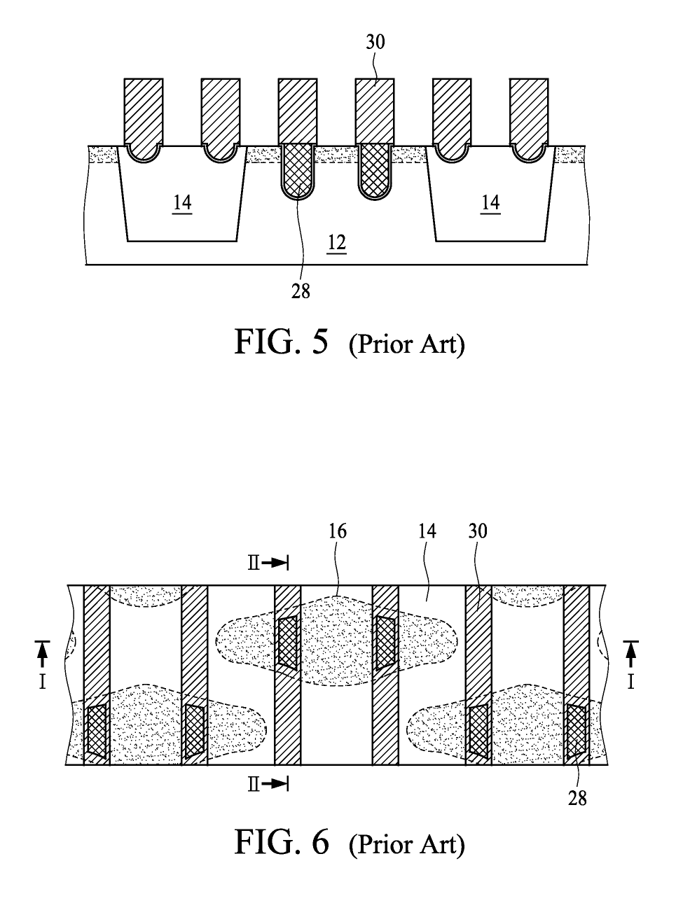

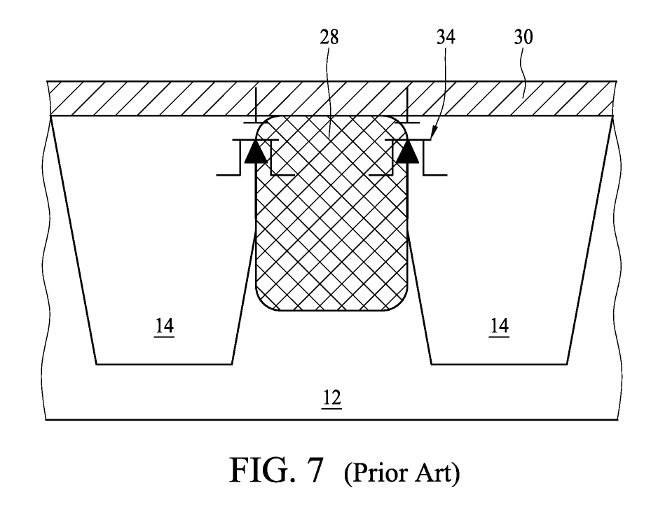

### DETAILED DESCRIPTION OF THE INVENTION

The following paragraphs will describe in detail the embodiment of the present invention in view of the drawings. However, the present invention can be fulfilled in many ways different from the embodiment, and should not be interpreted as the embodiment of the specification. In addition, the size of the layers and the regions in the drawings may be magnified for clear explanation, rather than drawn to actual scale.

Furthermore, the terms in the specification are used to describe the following embodiment only, and should not limit the scope of the present invention. As to “a” or “a layer” used in the specification, it also includes the meaning of the plural number unless there is a clear indication.

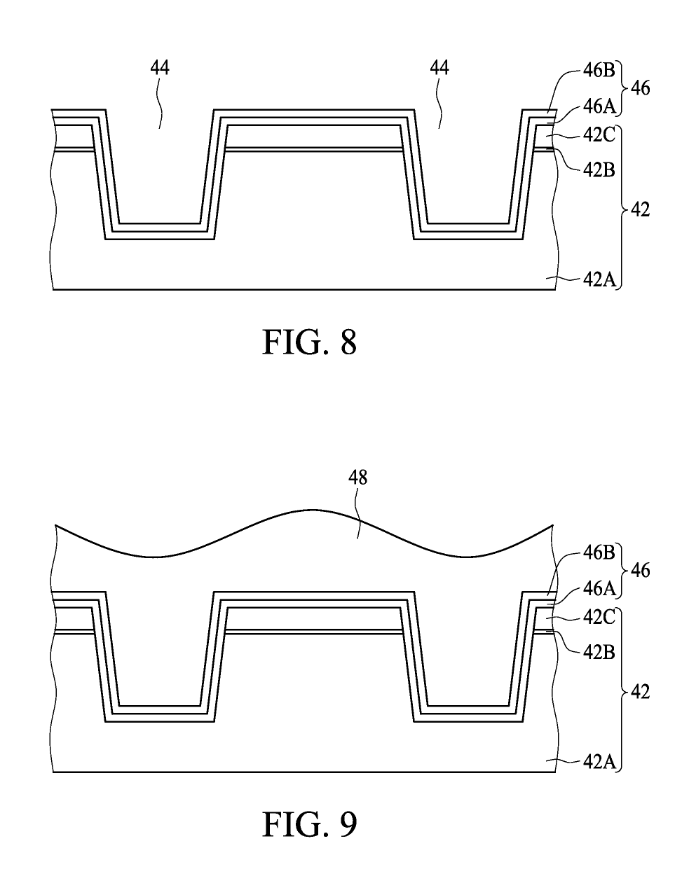

FIG. 8 to FIG. 15 illustrate a method for preparing a recessed gate structure according to one embodiment of the present invention. First, a substrate 42 is provided for preparing the recessed gate structure, wherein the substrate 42 includes a semiconductor substrate 42A and many dielectric layers can be optionally formed on the semiconductor substrate 42A, and the dielectric layers can be silicon oxide, silicon nitride or silicon oxy-nitride (SiON). According to this embodiment, a pad oxide layer 42B and a pad nitride layer 42C are deposited on the semiconductor substrate 42A in sequence, and a trench isolation region 44 is formed in the semiconductor substrate 42A, as shown in FIG. 8. Subsequently, a liner layer 46 consisting of dielectric material may be optionally formed on the surface of the substrate 42, wherein the surface of the substrate 42 includes the upper surface of the pad nitride layer 42C and the bottom surface and the sidewall surface of the trench isolation region 44. The liner layer 46 may consist of a liner silicon oxide layer 46A and a liner silicon nitride layer 46B formed on the surface of the substrate 42 in sequence.

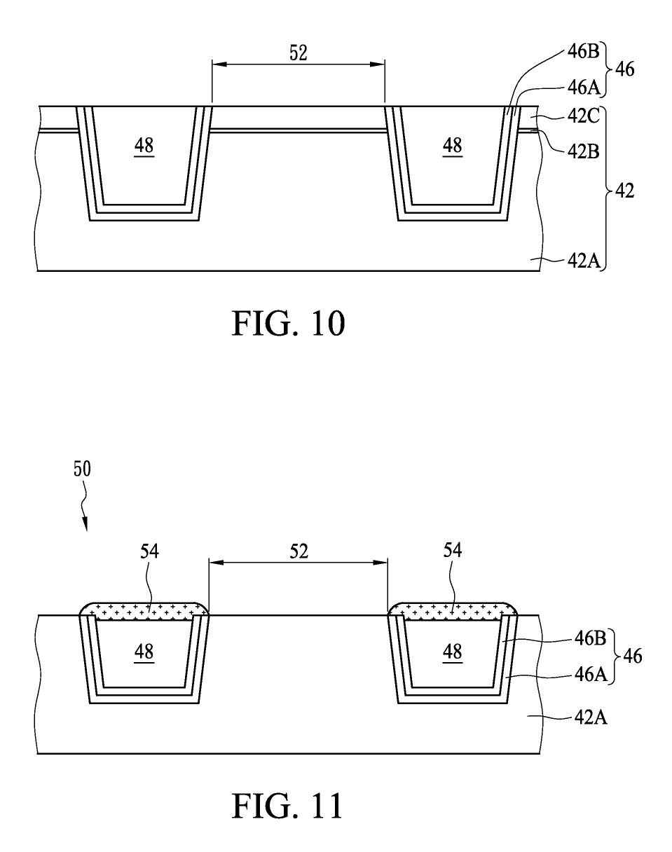

Referring to FIG. 9, a high-density chemical vapor phase deposition process (HDP-CVD) is performed to form an isolation dielectric layer 48; for example, the isolation dielectric layer 48 may include silicon oxide, i.e., STI oxide or HDP oxide. The isolation dielectric layer 48 fills the trench isolation region 44 and has a predetermined height. Referring to FIG. 10, a planarization process such as a chemical-mechanical polishing process is performed to remove a portion of the liner layer 46 above the active area 2 of the substrate 42 to expose the pad silicon oxide layer 42C such that only the trench isolation region 44 is filled with the isolation dielectric layer 48.

Referring to FIG. 11, an etching process is performed to remove the pad silicon oxide 42B and the pad silicon nitride 42C to expose the semiconductor substrate 42A. An etching barrier layer 54 is then formed on the surface of the isolation dielectric layer 48 close to an open end of the trench isolation region 44 to form a shallow trench isolation structure 50.

In particular, the etching barrier layer 54 can be prepared by a treating process having a certain reaction selectivity between the substrate 42 and the isolation dielectric layer 48 such that the etching barrier layer 54 can be optionally formed on an upper exposed area of the isolation dielectric layer 48, i.e. the etching barrier layer 54 is on the surface of the isolation dielectric layer 48 close to an open end of the trench isolation region 44. The treating process can be any process that has a certain reaction selectivity between the substrate 42 and the isolation dielectric layer 48; for example, the isolation dielectric layer 48 is made of silicon oxide such as STI oxide or HDP oxide and the exposed substrate 42 is the semiconductor substrate 42 such as single crystal silicon, and a nitridation process can form a nitrogen-containing barrier layer on the surface of the isolation dielectric layer 48, wherein the nitrogen-containing barrier layer can be silicon nitride layer or silicon oxy-nitride (SiOxNy) layer with nonzero integer of x and y. Since the nitridation reactivity of the semiconductor substrate 42A is lower than that of the STI oxide or HDP oxide, the nitrogen-containing barrier layer is formed only on the surface of the isolation dielectric layer 48. However, the preparation method of the etching barrier layer is not limited to this one. The nitridation process is performed by exposing the semiconductor substrate 42A in a nitrogen-containing atmosphere, and the exposing duration can be adjusted to prepare the etching barrier layer 54 with a desired thickness. For example, the nitridation process can be performed by one of the following: performing a rapid thermal process performed in a nitrogen-containing atmosphere, performing a diffusion process performed in a nitrogen-containing atmosphere, performing an implanting process configured to implant nitrogen-containing dopants, or performing a nitridation process performed in a nitrogen-containing furnace. The nitrogen-containing species in the nitrogen-containing atmosphere and the nitrogen-containing dopants can be selected from the group consisting of nitrogen, ammonia, nitrous oxide, nitric oxide and the combination thereof.

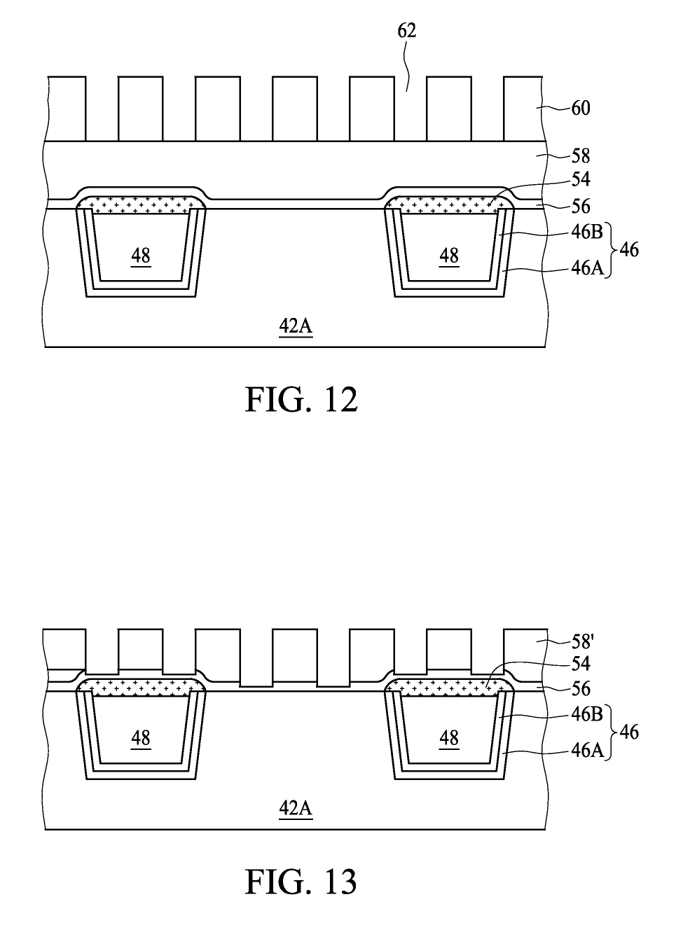

Referring to FIG. 12, a deposition process is performed to form a dielectric layer 56 and a mask layer 58 on the semiconductor substrate 42A in sequence, wherein the dielectric layer 56 can be made of any dielectric material known in the art and the major composition of the mask layer 58 is polysilicon. Subsequently, a photoresist layer 60 having a plurality of openings 62 is formed on the mask layer 58.

Referring to FIG. 13, a dry etching process is performed to remove a portion of the mask layer 58 under the openings 62 and stops on the dielectric layer 56 to form an etching mask 58′, and the photoresist layer 60 is then removed. Since the dry etching process is not performed to penetrate through the dielectric layer 56, damage to the etching barrier layer 54 can be avoided.

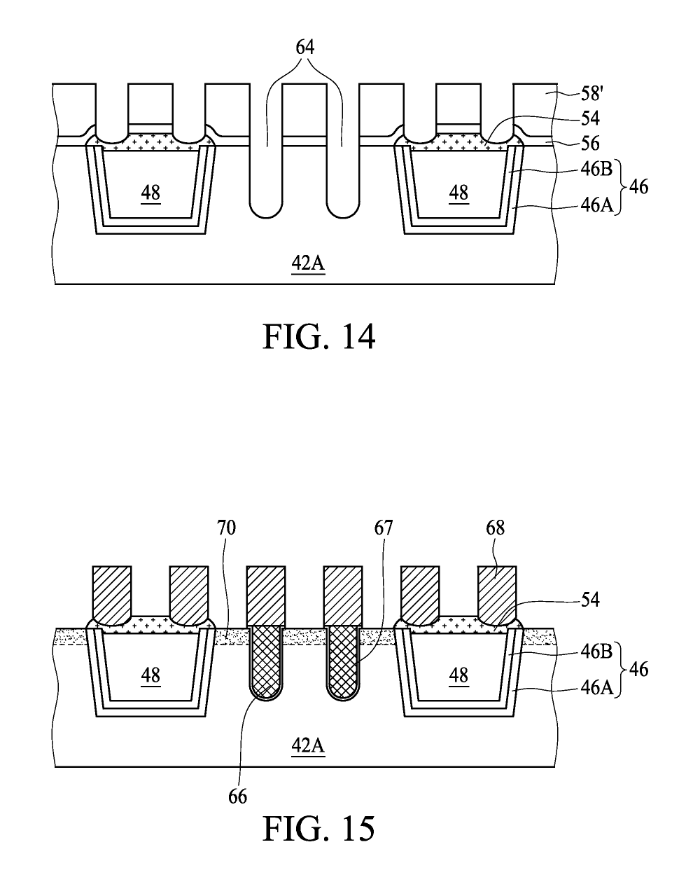

Referring to FIG. 14, the etching mask 58′ is used as a hard mask to perform a dry etching process such that the etching gas forms a plurality of gate trenches 64 in the semiconductor substrate 42A via the openings 62. Preferably, the etching gas can be a fluorine-containing gas such as fluorine, chlorine trifluoride, nitrogen trifluoride, sulfur hexafluoride, hexafluoro ethane or tetrafluoro methane. Since the etching gas has a high etching selectivity between the etching barrier layer 54 and the semiconductor substrate 42A, the dry etching process only selectively etches the semiconductor substrate 42A and does not etch the etching barrier layer 54 on the isolation dielectric layer 48 such that the profile of the shallow trench isolation structure 50 is not changed, i.e., no depression is formed in the isolation dielectric layer 48.

Referring to FIG. 15, the etching mask 58′ and the dielectric layer 56 are removed after the dry etching process, and recessed gates 66 are formed to fill the gate trenches 64, wherein an isolation layer 67 can be optionally formed between the gate trench 64 and the recessed gate 66. Subsequently, a word line 68 is formed to electrically connect the recessed gates 66, and doped regions 70 are formed in the semiconductor substrate 42A at two sides of the gate trenches 64 by implanting n-type or p-type dopants.

The above-described embodiments of the present invention are intended to be illustrative only. Numerous alternative embodiments may be devised by those skilled in the art without departing from the scope of the following claims.

What is claimed is:

1. A method for forming a shallow trench isolation structure, comprising the steps of:
providing a substrate having a trench isolation region;
filling the trench isolation region with an isolation dielectric layer;
performing a planarization process to remove a portion of the isolation dielectric layer above the surface of the semiconductor substrate such that the other portion of the isolation dielectric layer fills the trench isolation region; and
performing a treating process to convert an upper exposed area of the isolation dielectric layer into an etching barrier layer on the surface of the isolation dielectric layer close to an open end of the trench isolation region.

2. The method for forming a shallow trench isolation structure of claim 1, wherein the treating process is a rapid thermal process performed in a nitrogen-containing atmosphere.

3. The method for forming a shallow trench isolation structure of claim 1, wherein the treating process is a diffusion process performed in a nitrogen-containing atmosphere.

4. The method for forming a shallow trench isolation structure of claim 1, wherein the treating process is an implanting process configured to implant nitrogen-containing dopants.

5. The method for forming a shallow trench isolation structure of claim 1, wherein the treating process is a nitridation process performed in a nitrogen-containing furnace.

6. The method for forming a shallow trench isolation structure of claim 1, wherein the etching barrier layer comprises silicon and nitrogen.

7. The method for forming a shallow trench isolation structure of claim 1, wherein the etching barrier layer includes SiOxNy, and x and y are nonzero integers.

8. A method for preparing a recessed gate structure, comprising the steps of:
providing a substrate having a trench isolation region;
filling the trench isolation region with an isolation dielectric layer;
performing a planarization process to remove a portion of the isolation dielectric layer above the surface of the semiconductor substrate such that the other portion of the isolation dielectric layer fills the trench isolation region;
performing a treating process to convert an upper exposed area of the isolation dielectric layer into an etching barrier layer on the surface of the isolation dielectric layer close to an open end of the trench isolation region;
performing an etching process to form a plurality of gate trenches in an area not covered by the etching barrier layer; and
filling the gate trenches to form recessed gates with a predetermined height.

9. The method for preparing a recessed gate structure of claim 8, wherein the etching process uses an etching gas having a high etching selectivity between the etching barrier layer and the semiconductor substrate.

10. The method for preparing a recessed gate structure of claim 8, wherein the treating process is a rapid thermal process performed in a nitrogen-containing atmosphere.

11. The method for preparing a recessed gate structure of claim 8, wherein the treating process is a diffusion process performed in a nitrogen-containing atmosphere.

12. The method for preparing a recessed gate structure of claim 8, wherein the treating process is an implanting process configured to implant nitrogen-containing dopants.

13. The method for preparing a recessed gate structure of claim 8, wherein the treating process is a nitridation process performed in a nitrogen-containing furnace.

14. The method for preparing a recessed gate structure of claim 8, wherein the etching barrier layer comprises silicon and nitrogen.

15. The method for preparing a recessed gate structure of claim 8, wherein the etching barrier layer includes SiOxNy, and x and y are nonzero integers.
